(19) United States
(12) Patent Application Publication
(10) Pub. No.: US 2018/0323726 A1
(43) Pub. Date: Nov. 8, 2018

(54) INITIALIZING VIRTUAL OSCILLATOR CONTROL

(71) Applicant: SunPower Corporation, San Jose, CA (US)

(72) Inventor: Fernando Rodriguez, Austin, TX (US)

(73) Assignee: SunPower Corporation, San Jose, CA (US)

(21) Appl. No.: 15/956,011

(22) Filed: Apr. 18, 2018

Related U.S. Application Data
(60) Provisional application No. 62/500,934, filed on May 3, 2017.

(51) Int. Cl. H02M 7/537; G01R 19/25; G01R 21/133; G01R 35/04; H02J 3/38

(52) U.S. Cl. CPC H02M 7/537; G01R 19/2513; H02M 2001/0012; G01R 35/04; H02J 3/38; G01R 21/133

(57) ABSTRACT

A first micro-inverter and a second micro-inverter are arranged to source a load. The micro-inverters include a virtual oscillator control (VOC) to provide voltage commands to an hysteretic current regulator. The hysteretic current regulator provides instructions to the DC/AC inverter to output voltage to the load. When the second micro-inverter is powered on, an initialization process is executed to provide values to its VOC that reduces transients and improves the synchronization process with the first micro-inverter.

### RELATED APPLICATIONS

This application claims priority to U.S. Provisional application 62/500,934, which was filed on May 3, 2017 and entitled “Initializing Virtual Oscillator Control”. The '934 application is incorporated by reference in its entirety into this application.

This invention was made with government support under Prime Contract No. DE-AC36-08G028308 and Subcontract No. LHQ-6-62581-01, both of which were awarded by U.S. Department of Energy. The government has certain rights in the invention.

### BACKGROUND

Photovoltaic (PV) cells, commonly known as solar cells, are devices for conversion of solar radiation into electrical energy. Generally, solar radiation impinging on the surface of, and entering into, the substrate of a solar cell creates electron and hole pairs in the bulk of the substrate. The electron and hole pairs migrate to p-doped and n-doped regions in the substrate, thereby creating a voltage differential between the doped regions. The doped regions are connected to the conductive regions on the solar cell to direct an electrical current from the cell to an external circuit. When PV cells are combined in an array such as a PV module, the electrical energy collected from all of the PV cells can be combined in series and parallel arrangements to provide power with a certain voltage and current.

Start up and shut down of PV modules in series and parallel arrangements may be used to change the voltage or current supplied to a load. For example, PV modules connected in parallel may be supplemented by additional PV modules to increase the current to a load and PV modules connected in series may be supplemented with additional PV modules to increase the voltage at a load. Conversely, the removal of one or more PV modules from a series or parallel connection to a system may also be performed to manage the available voltage or current at a load.

### BRIEF DESCRIPTION OF THE DRAWINGS

FIG. 1 illustrates an exemplary arrangement of a first micro-inverter and a second micro-inverter sourcing a load according to some embodiments.

FIG. 2 illustrates an exemplary waveform with a current transient during startup initialization when the second micro-inverter is turned on according to some embodiments.

FIG. 3 illustrates portions of the exemplary arrangement of the micro-inverters of FIG. 1 in greater detail.

FIG. 4 illustrates an exemplary waveform showing the current at the load at the completion of startup initialization when the second micro-inverter is powered on along with the first micro-inverter according to some embodiments.

FIG. 5 illustrates a flowchart for illustrating an exemplary method for initializing a second micro-inverter having a VOC according to some embodiments.

### DETAILED DESCRIPTION

The following detailed description is merely illustrative in nature and is not intended to limit the embodiments of the subject matter of the application or uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

### Terminology

The following paragraphs provide definitions and/or context for terms found in this disclosure (including the appended claims):

“Comprising.” This term is open-ended. As used in the appended claims, this term does not foreclose additional structure or steps. “Configured To.” Various units or components may be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. § 112 (f) for that unit/component.

“First,” “Second,” etc. As used herein, these terms are used as labels for nouns that they precede, and do not imply any type of ordering (e.g., spatial, temporal, logical, etc.). For example, reference to a “first” micro-inverter does not necessarily imply that this micro-inverter is the first micro-inverter in a sequence; instead the term “first” is used to differentiate this micro-inverter from another micro-inverter (e.g., a “second” micro-inverter).

“Based On.” As used herein, this term is used to describe one or more factors that affect a determination. This term does not foreclose additional factors that may affect a determination. That is, a determination may be solely based on those factors or based, at least in part, on those factors. Consider the phrase “determine A based on B.” While B may be a factor that affects the determination of A, such a phrase does not foreclose the determination of A from also being based on C. In other instances, A may be determined based solely on B.

“Coupled”—The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

“Inhibit”—As used herein, inhibit is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, and/or effect which might otherwise occur. Accordingly, when a component, element, or feature is referred to as inhibiting a result or state, it need not completely prevent or eliminate the result or state.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

In the following description, numerous specific details are set forth, such as specific operations, in order to provide a thorough understanding of embodiments of the present disclosure. It will be apparent to one skilled in the art that embodiments of the present disclosure may be practiced without these specific details. In other instances, well-known techniques are not described in detail in order to not unnecessarily obscure embodiments of the present disclosure.

This specification first describes exemplary micro-inverters that can include the disclosed arrangement, followed by a more detailed explanation of various embodiments of micro-inverter arrangements. The specification also includes a description of exemplary methods for initializing virtual oscillator control (VOC) at initialization startup, activation after initialization, and at other times within a micro-inverter arrangement. Various examples are provided throughout.

Virtual oscillator control (VOC) may be considered a decentralized control module for islanded microgrid inverters that implement an algorithm or logical circuit to control a micro-inverter such that it mimics a nonlinear oscillator. VOC may assist a micro-inverter synchronize its voltage output with other micro-inverters within an electrically connected arrangement and share the load power in proportion to its power rating without necessitating extra communications. VOCs can enable reliable control of distributed electrically connected micro-inverters in photovoltaic (PV) integrated systems. VOCs may implement algorithms and control processes to achieve these objectives during initialization as well as operation and shut down of one or more micro-inverters. VOCs may also implement logical circuits to perform the processes taught herein. VOC may act at startup initialization, which is when a micro-inverter is first brought online in a system as well as at other times, such as activation after initialization, which is when a micro-inverter has already been brought online but is not presently producing an AC output and is again being turned on or activated to source a load already being sourced by one or more micro-inverters.

When VOC algorithms are applied to an arrangement of two or more electrically connected micro-inverters, the VOC parameters should preferably be initialized in embodiments in a controlled manner in order to avoid an undesired current or voltage transient at a turn-on or initiation stage or both of a micro-inverter. More specifically, embodiments may serve to reduce current transients that may occur when a second or additional micro-inverter of a distributed grouping of micro-inverters source current or voltage or power to a resistive load. For example, if a first micro-inverter powers an AC-voltage across the load when a second micro-inverter is brought online to power the load, if VOC parameters of the second micro-inverter are not initialized properly, then a voltage or current transient can occur across the load. Thus, embodiments may include processes to initialize the VOC function applied in a micro-inverter. These processes may serve to reduce the transient voltage or current when the micro-inverter, a second or additional micro-inverter in a distributed set, is powered on and/or initialized or otherwise brought online.

In some embodiments, when a second micro-inverter is powered on otherwise brought online, the initial conditions of the VOC and the voltage regulator are preferably set so as to minimize or avoid a load voltage or current transient. This situation may be achieved by providing a delayed I_{synch} command that coaxes the VOC into an operation condition that sets the appropriate initial conditions. For a micro-inverter with a hysteric current regulator, it is preferred in embodiments to initialize both the VOC and the voltage regulator when bringing a micro-inverter online. As shown and discussed herein, the current command I_{synch} may be delayed during an initialization startup or other activation mode, after being generated and before being used as an input for the VOC. This delay can be carried out by holding the I_{synch} current commend in a register for one or more clock cycles. In so doing, erroneous logical loops caused by using a premature current command output of zero as part of the input in the VOC can be mitigated or avoided. In certain embodiments, to avoid a zero-commanded current or other nonlogical command, disclosed embodiments may set initial conditions by connecting the output of the voltage regulator to the VOC via a unit delay block before the second micro-inverter is powered on or otherwise brought online. The voltage regulator may preferably set the current command so that the VOC produces a voltage command equal to the sensed voltage because the voltage feedback is equal to the load voltage resulting from the first micro-inverter powering the load. In embodiments, this feature can serve to set the initial conditions of both the VOC and the voltage regulator without the need of additional synchronization blocks and logic in the VOC or elsewhere with respect to setting a command current for the VOC to use when starting up an additional micro-inverter for purposes of matching an existing current or voltage waveform.

In some embodiments, the VOC of a second or additional micro-inverter may generate an output voltage command that is subsequently translated into a current command by a voltage regulator or other component or module. The micro-inverter may fulfill this current command with an hysteric current regulator and the hysteric current regulator may generate the commanded voltage over the load. This arrangement is preferred when a single micro-inverter is powered on or otherwise brought online.

During initialization startup mode or other activation mode bringing the micro-inverter online, embodiments may derive I_{synch} by estimating values of initial control conditions for the additional micro-inverter should be in order to accommodate the operation of the operating micro-inverter(s) and the load demands. Instantaneous as well as average voltage and current for a prescribed amount of time may be considered when setting the initial control conditions. Once the initial control conditions are set embodiments may rely on the hysteretic current regulation to reach a desired current waveform during the startup and initialization and after initialization is complete. In embodiments, a voltage regulator or other component or module may receive voltage command and convert it to a current command I*. This current command I* may be delayed and refed back into the VOC as an I_{synch} command. In operation, once a sensed voltage V* is within an acceptable range of a command voltage V_{command} synchronization may be presumed and initialization may be considered complete. This acceptable range may be a percentage variance such as 1%-5% between output waveform and waveform at the load. Other ranges, both smaller and larger may also be employed. Once bringing the microinverter online is complete, e.g., the output is within a prescribed range for a predetermined period of time, the delay of I_{synch} may end. Through the use of the VOC in this way, embodiments may reduce the need for additional complexity of the VOC or other components or modules for purposes of reducing or eliminating transients during initialization or otherwise bringing the micro-inverter online. Activation, bringing online, and initialization startup and variations thereof are each instances of when embodiments may be practiced or otherwise employed.

Embodiments may also employ PLC line communications at startup initialization and activation. Enable instructions, vi PLC or other communication method, may be sent through a selector switch or other component, or directly to a VOC in embodiments in order to provide initial conditions for the VOC of a second or additional micro-inverter. These initial conditions may include internal states for the VOC block, where these internal states may include initial conditions for a VOC so waveforms of the presently operating micro-inverters may be synched or otherwise corresponded to by a VOC of the micro-inverter being brought online.

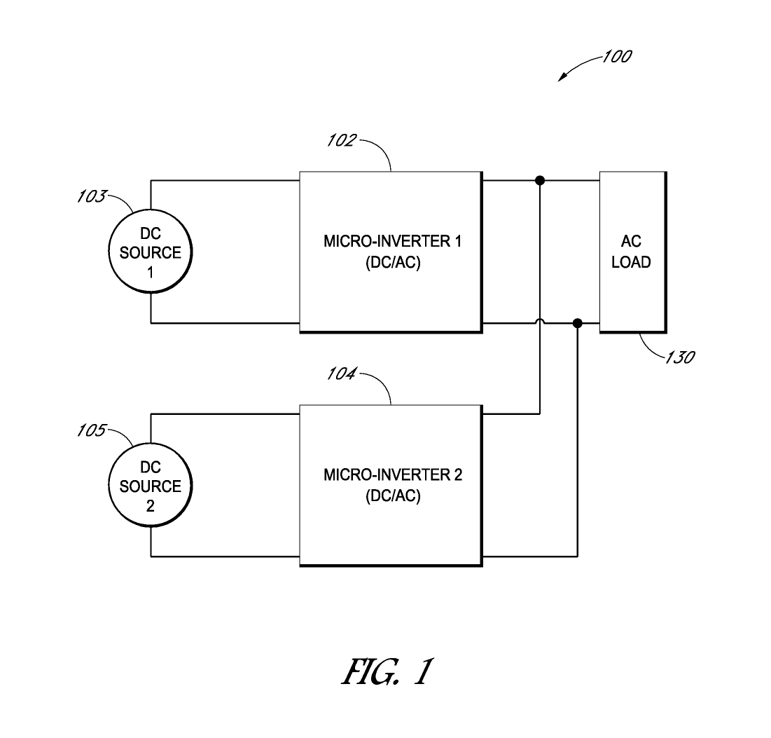

FIG. 1 depicts an exemplary arrangement of distributed grouping 100 of microinverters comprising a first voltage source micro-inverter 102 and a second voltage source micro-inverter 104 sourcing a load 130 according to possible embodiments. First micro-inverter 102 is connected to a direct current (DC) power source 103 and second micro-inverter 104 is connected to a DC power source 105. Preferably, DC powers sources 103 and 105 include PV cells that may be switched to provide power to load 130 via micro-inverters 102 and 104. Micro-inverters 102 and 104 are configured to and operate to convert and filter the incoming power from DC to AC. The DC sources may also be batteries, wind turbines, and other DC sources.

In some circumstances, micro-inverter 102 may provide power to load 130 while micro-inverter 104 does not. Reasons for this may vary, such as demands of load 130 or the availability of micro-inverter 104 or the availability of DC sources 1 or 2. Micro-inverter 102 can instruct micro-inverter 104 to turn on and supply power to load 130. Other command sources may also be employed for turn on instructions. For example, an initiate or start power output command may come from the micro-inverter that is itself being powered on, from another micro-inverter, from a centralized control, and/or from some high-level dispatching algorithm. When the micro-inverter is turning its own power on a housekeeping power supply may be employed to power the control circuitry of the micro-inverter without necessitating an active power on state for the micro-inverter. As noted above, a transient problem may occur when the second micro-inverter turns on by not having the power outputs synched properly.

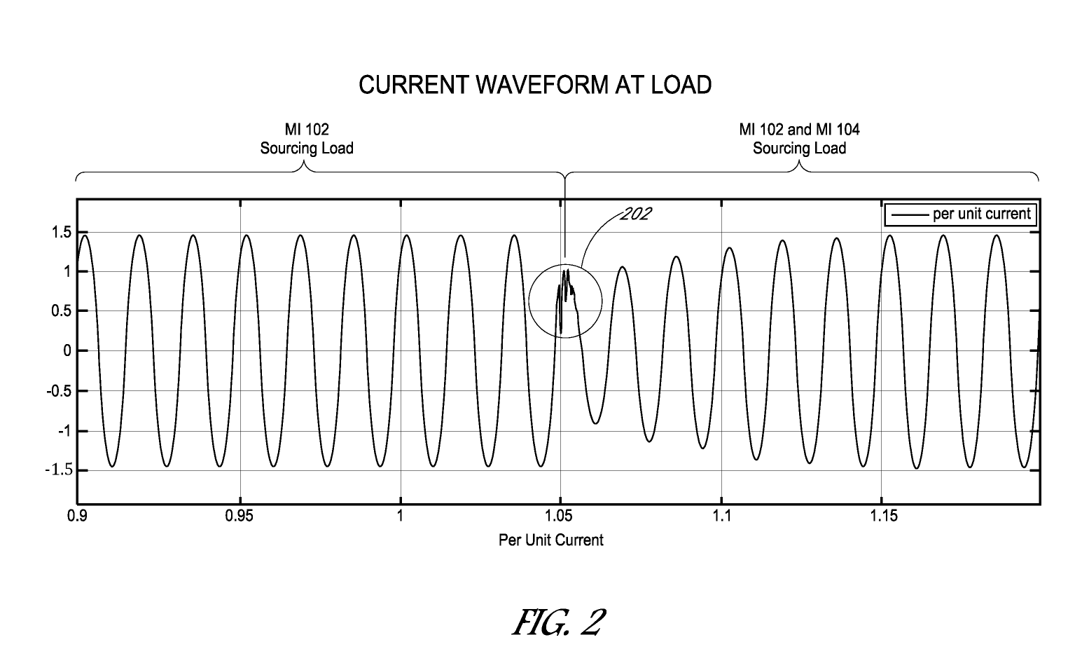

FIG. 2 depicts an example of a waveform having a current transient 202 when micro-inverter 104 is turned on as may occur in embodiments. This transient 202 may also include a few cycles of subsequent nonuniform waveforms, as is also shown in FIG. 2 subsequent to transient 202. The circuitry within micro-inverter 104 is not initialized in sync with the waveform, which causes transient 202. As can be seen, transient 202 may cause irregularities in the waveform provided to load 130. The amount of current supplied to load 130 may drop below desired levels. Alternatively, transient 202 may be manifested as a spike in current or power to load 130, which results in potential damage to circuits or equipment or other unwanted outcomes. Embodiments can provide an initialization configuration or process serving to reduce the occurrence or effect of transient 202 and related nonuniform waveforms at a first or subsequent startup of a supplemental converter, such as a micro-inverter.

Although FIG. 1 shows two micro-inverters, the disclosed arrangement may include additional micro-inverters coupled to load 130 as well as to multiple loads, as would be common when connecting to the electrical grid. As each additional micro-inverter is brought online, initialization problems may occur that cause a voltage or current transient across load 130. The embodiments disclosed herein may also be implemented for additional micro-inverters or other circuits manipulating and sending electrical power into an existing electrical grid with an existing power waveform.

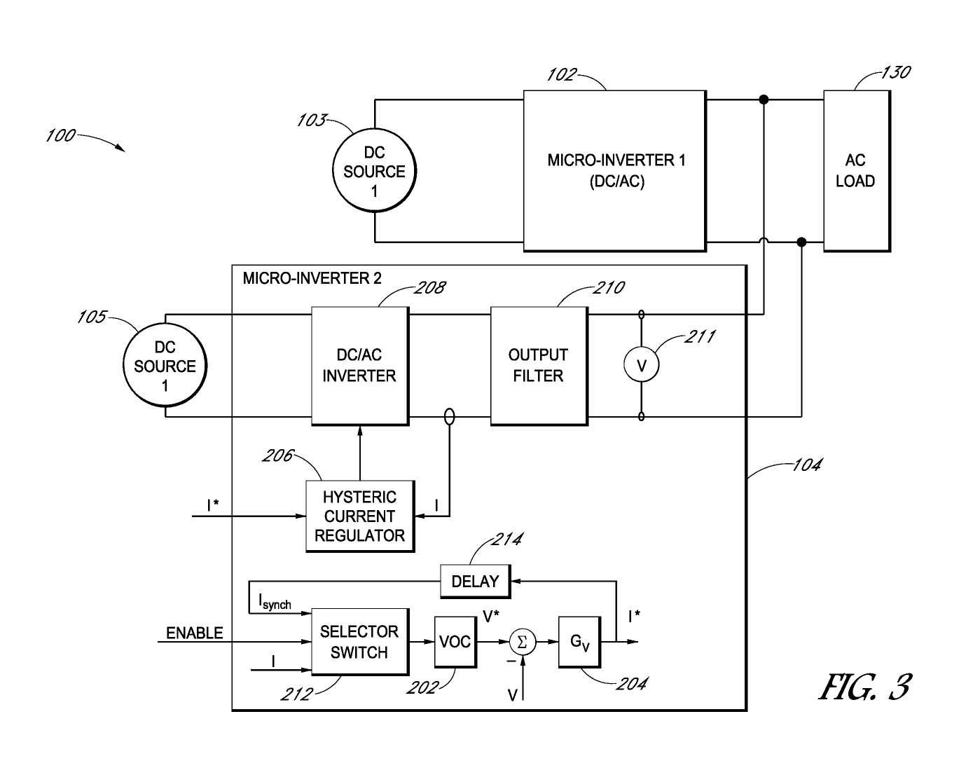

FIG. 3 depicts the distributed grouping 100 of micro-inverters 102 and 104 in greater detail. FIG. 3 shows a block diagram of the components within micro-inverter 104. Micro-inverters 102 and 104 provide AC power to load 130. To accomplish this, micro-inverters 102 and 104 may implement a virtual oscillator control (VOC) 202 as taught herein.

In some embodiments, VOC 202 may generate an output voltage command V* for micro-inverter 104 that is translated into a current command I* by voltage regulator 204. Micro-inverter 104 may then fulfill the current command with hysteretic current regulator 206. Hysteretic current regulator 206 may instruct DC/AC inverter 208 to generate a commanded voltage across load 130. The voltage may then be output through output filter 210, where a voltage V may be sensed. For example, a sensor 211 may be placed across the output connections from output filter 210.

VOC 202 may implement one or more algorithms to operate the micro-inverters. Logical circuitry may also be employed in embodiments. The algorithms and/or logical circuitry may manage operations and generate signals and commands such that the voltage command V* is proper or within a desired range in order to manage the current command to hysteretic current regulator 206 in a certain range. Hysteresis current control in micro-inverters may provide advantages such as quick response time, internal limiting capacity, reduced power losses, and stability. Regulator 206 may receive a sensed current I from DC/AC inverter 208, which may be fed back to VOC 202 through selector switch 212.

In embodiments, VOC 202 may receive the sensed current I and applies VOC's internal algorithms or fixed circuitry to produce the next voltage command V*. The voltage command V* may be compared to sensed voltage V, which is disclosed in greater detail below. The voltage command V* may be directly fed into voltage regulator 204. Voltage regulator 204 may convert the voltage command into current command I*. This process may be repeated within the micro-inverter to provide a desired output voltage. In embodiments, an analog filter may be placed on the output of voltage regulator 204, filters may also be placed in series with the feedback signals V and I instead of or in addition to on the output of the voltage regulator 204. Filters may be located in other portions of the circuit topology as well.

In embodiments, VOC 202 may provide the function of being able to monitor and change the output voltage by updating the algorithms used within. This feature can serve to avoid having to change the circuitry within the micro-inverter. While micro-inverters may act like current sources in that they do not regulate the voltage, in embodiments, VOC 202 can control the output voltage for utilization within microgrids, such as the one shown by arrangement 100.

In embodiments, micro-inverters coupled to PV, such as power sources 103 and 105, may also use a current regulator, such as hysteretic current regulator 206. Hysteretic current regulator 206 may allow the micro-inverter to meet high efficiency requirements and to manage the switch output point versus a reset point for current management.

The above description of the features for VOC 202 and hysteretic current regulator 206 applies to micro-inverters 102 and 104 as well as micro-inverter in other embodiments. As noted above, in embodiments, when micro-inverter 102 is providing voltage to load 130 and micro-inverter 104 is ordered to begin supplying voltage as well. VOC 202 of micro-inverter 104 may operate to synchronize with the output parameters of micro-inverter 102 to supply steady voltage to load 130. As noted embodiments may serve to set initial conditions via an enable signal such that transient current waveforms are reduced if not eliminated. Embodiments may also accomplish proper initialization by providing a delayed synchronization current I_{synch} that triggers VOC 202 into an operation condition that sets the appropriate initial conditions. For example, if VOC 202 and regulator 204 started the algorithms for determining voltage command V* with a zero, then transients would occur until micro-inverter 104 goes through one or more cycles to generate a sensed current I to be fed back through the VOC process. Thus, VOC 202 should preferably use initial states for its algorithms and to apply its functions within micro-inverter 104. These initial states promote VOC 202 and voltage regulator 204 to synch before applying voltage to load 130. To do so, micro-inverter 104 includes a unit delay block 214 that receives current I_{synch} from voltage regulator 204 to be fed back to selector switch 212. Current I_{synch} may be an estimate of what the control current should be before micro-inverter 104 powers on. The ENABLE signal shown in FIG. 3 may also be employed to supply initial states of the VOC.

Before micro-inverter 104 is powered on, its initial conditions are preferably set by connecting the output of voltage regulator 204 to VOC 202 via delay block 214. Because the voltage feedback V is equal or substantially equal to the load voltage resulting from micro-inverter 102 powering load 130, voltage regulator 206 will preferably set the current command I* so that VOC 202 provides a voltage command V* equal to the sensed voltage V. This feature serves to preferably set the initial conditions of VOC 202 and voltage regulator 204 without the need of additional synchronization and blocks. This also preferably allows VOC 202 and voltage regulator 204 to operate within an architecture using hysteretic current regulator 206.

In some embodiments, delay block 214 is a register that stores current command I* to then produce current I_{synch}. The delay avoids an algebraic loop within the functions of VOC 202 and voltage regulator 206. Current command I* is stored in delay block 214 until the next cycle. It is then used as I_{synch} to calculate voltage command V.

This process of using the delay current command I* is stopped once the sensed voltage V is within an acceptable range of V*. The difference between these two values should preferably be below a threshold. Once achieved, the initialization startup or activation or synchronization mode is stopped. Selector switch 212 may then use sensed current I as input to VOC 202.

Selector switch 212 may receive an ENABLE command from power line commands to power on micro-inverter 104. The ENABLE command may also be received from micro-inverter 102 when it is determined that additional power is needed to load 130. Selector switch 102 then may read delay block 214 to determine whether a value for current I_{synch} is available. Once the sensed voltage V is received at voltage regulator 206, current command I* is preferably provided to delay block 212. Preferably, this occurs in a single cycle of the current command generation process but additional cycles may be used as a target voltage for an existing waveform is reached. The selector switch in embodiments may receive an ENABLE signal that is configured to select a switch input and enable the microinverter to produce power. The ENABLE signal may perform other functions as well.

Arrangement 100 may include additional micro-inverters that supply voltage to load 130. As each one is powered on, the disclosed process is used to initialize the applicable VOC and synchronize the output with the operating micro-inverters. In other embodiments, the disclosed processes may be used to bring multiple micro-inverters to a powered-on state operating with a powered micro-inverter.

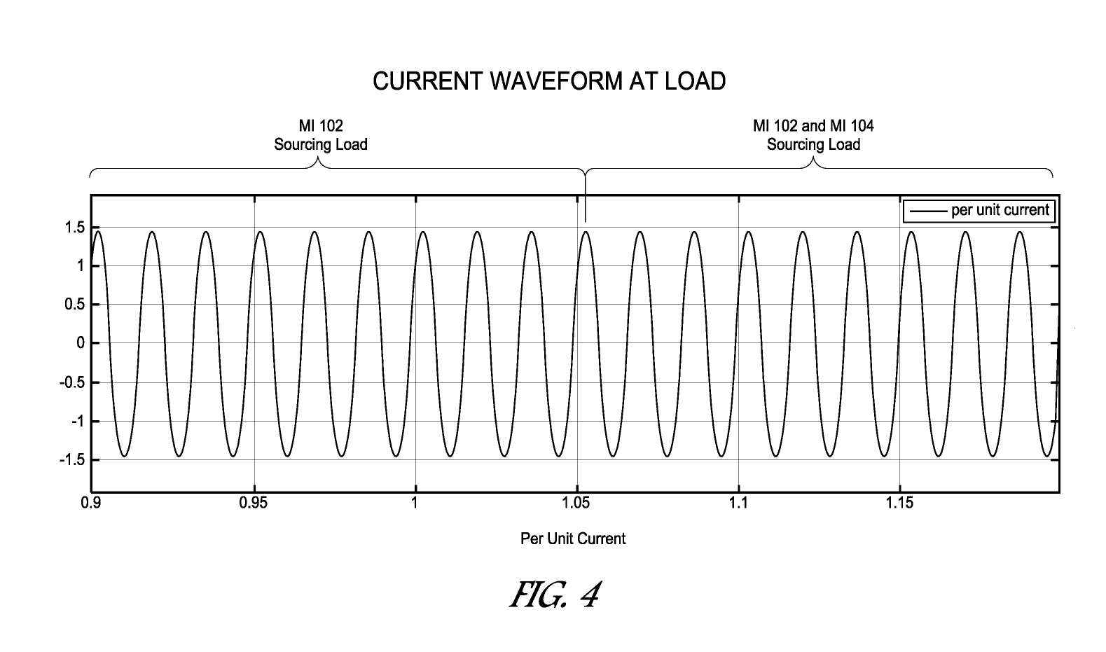

FIG. 4 depicts an example of a waveform showing the current at load 130 when micro-inverter 104 is powered on with micro-inverter 102 according to some embodiments. As can be seen, any transition as a result of the power on synchronization is reduced. In embodiments, waveforms preferably synchronize in a timely manner with little deviation from the waveform of the current to the load from micro-inverter 102 during and after initialization.

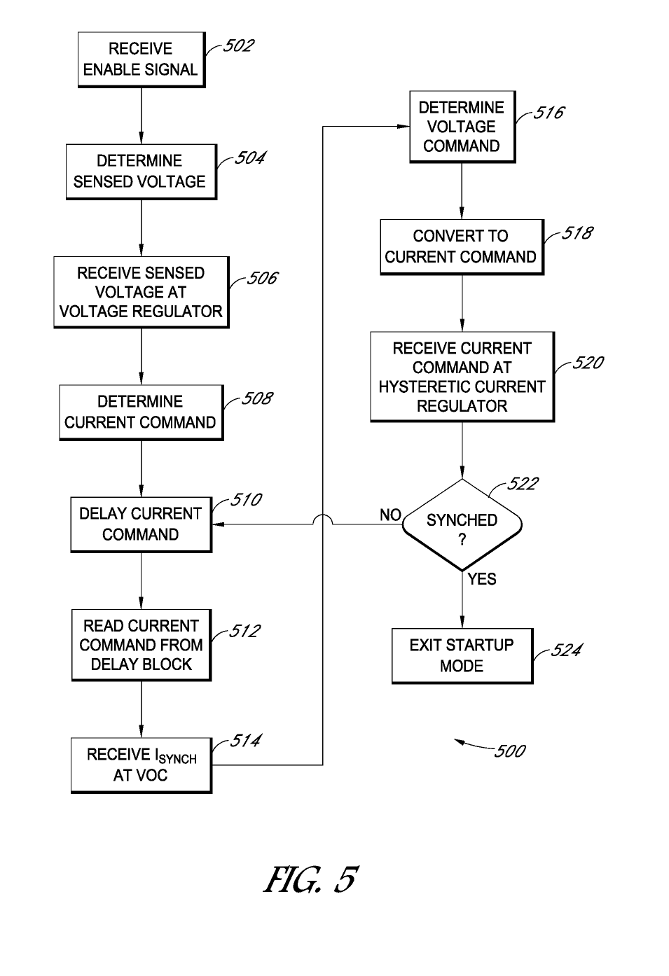

Turning now to FIG. 5, a flowchart 500 illustrating a method for initializing a micro-inverter having VOC 202 is shown, according to some embodiments. In certain embodiments, the method of FIG. 5 can include additional (or fewer) actions than illustrated. The description of FIG. 5 may include references to features in FIGS. 1-4 for illustrative purposes, but the embodiments disclosed by FIG. 5 are not limited to these features and may be carried out with only some of these features as well as all of these features.

Step 502 executes by receiving an ENABLE signal at selector switch 212 of a second micro-inverter 104. The second micro-inverter may be connected to a load 130 along with a first micro-inverter 102. At step 502, micro-inverter 102 is already providing power to load 130. Micro-inverter 104 receives the ENABLE signal that instructs it to power on as well. At this point, micro-inverter 104 may enter a “startup” or synch mode to have the VOC of the second micro-inverter synch with the VOC of the first micro-inverter so that the power delivered to load 130 is not out of phase. Step 504 executes by determining the sensed voltage V_{sensed} being applied to load 130 from micro-inverter 102. A voltage sensor 211 may determine the voltage V_{sensed} being applied to load 130 and provide it to micro-inverter 104. Step 506 executes by receiving the sensed voltage V_{sensed} at voltage regulator 204. Step 508 executes by determining a current command I* based on the sensed voltage. Voltage regulator 204 may implement algorithms that receive a voltage input and then provide a current command output to be applied to DC/AC inverter 208 via hysteretic current regulator 206. Thus, the current command I* instructs the voltage to be output by inverter 208 and to load 130 from micro-inverter 104.

In start-up or other going online mode, however, the current command I* is delayed in step 510 before being fed back to selector switch 212. Preferably, the current command I* is stored in a unit delay block 214 for one wave cycle although more cycles or other delay parameters, e.g., a clock cycle, may be employed. After the cycle is completed, step 512 executes by reading the current command I* from delay block 214 to selector switch 212. The current command I* is now referred to as a synch current I_{synch}. In other words, the value is not a current command as much as one used to synch VOC 202 even though the value of I* and I_{synch} is preferably identical.

Step 514 executes by receiving current I_{synch} at VOC 202. Step 516 executes by determining a voltage command V* based on current I_{synch}. Thus, VOC 202 does not receive a “zero” or other value at start up or other going online cycles that can cause problems in initializing the functions incorporated therein because of a nonsensical initial command value. The initialization also preferably prevents transients from occurring in the output voltage to load 130. Current I_{synch} may, therefore, provide a feasible value to begin the synchronization process with micro-inverter 102. VOC 202 is, accordingly, able to provide a voltage command V* that will preferably reduce the effects of transients with the arrangement of micro-inverters.

Step 518 executes by converting the voltage command V* to current command I* by voltage regulator 204. This current command I* may be used within micro-inverter 104. Thus, step 520 executes by receiving the current command I* at hysteretic current regulator 206. Based on the current command I*, regulator 206 may tell DC/AC inverter 208 which output voltage to provide.

Step 522 executes by determining whether the output voltages between micro-inverters 102 and 104 are in synch. Voltage command V* may be compared to the sensed voltage V_{sensed} to determine a difference between both values. If the difference is within a range or below a threshold, then the output voltage signals of the newly initiated micro-inverter and the existing waveform to the load should be in synch. Thus, if step 522 is yes, then step 524 executes by exiting the startup or synch mode. Selector switch 212 may now input sensed current I_{sensed} from inverter 208 as opposed to using current I_{synch}. VOC 202 now uses I_{sensed} to determine the voltage command V*. In embodiments, switching from I_{synch} to I_{sensed} may occur near the estimated zero-crossing of the sensed voltage. In so doing, the micro-inverter being started is started near or at the zero-crossing.

If step 522 is no, then flowchart 500 returns to step 510 by delaying the current command I*. The process disclosed above may be repeated until the difference between voltage command V* and sensed voltage is within a predetermined range or below a threshold. Thus, the embodiments disclosed by flowchart 500 initialize the VOC used in a second micro-inverter. The disclosed process reduces the transient when the second micro-inverter is powered on and synchronizes with the first micro-inverter to provide power to a load from the multiple-inverter topology.

Although specific embodiments have been described above, these embodiments are not intended to limit the scope of the present disclosure, even where only a single embodiment is described with respect to a particular feature. Examples of features and processes provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed is:

1. An arrangement of micro-inverters to source a load comprising:
a first micro-inverter to provide AC power to the load; and
a second micro-inverter to provide AC power to the load, the second micro-inverter including
a DC/AC inverter to generate the AC power;
an hysteretic current regulator configured to provide an instruction to the inverter to provide the AC power based on a current command;
a virtual oscillator control configured to generate a voltage command;
a voltage regulator configured to convert the voltage command to the current command; and
a delay block coupled between the virtual oscillator control and the voltage regulator, wherein the delay block receives an initial current command from the voltage regulator during a startup mode and, after a cycle, provides the current command to the virtual oscillator control in order to initialize a function of the virtual oscillator control.

2. The arrangement of claim 1, further comprising a selector switch coupled to the virtual oscillator control to provide the delayed initial current command from the delay block.

3. The arrangement of claim 1, wherein the delay block is a register.

4. The arrangement of claim 1, wherein the voltage regulator is configured to receive a sensed voltage of the first micro-inverter during the startup mode.

5. The arrangement of claim 4, wherein the voltage regulator is configured to generate the initial current command based on the sensed voltage.

6. The arrangement of claim 1, wherein the virtual oscillator control is to receive a sensed current via the selector switch after exiting the startup mode.

7. The arrangement of claim 1, wherein the startup mode is completed when the output signals from the micro-inverters are synchronized.

8. A method to initialize a virtual oscillator control in a second micro-inverter connected to a load along with a first micro-inverter, the method comprising:
receiving a sensed voltage from the first micro-inverter;
determining a current command from the sensed voltage;
delaying the current command for a cycle;
receiving the current command at the virtual oscillator control to initialize a function at the virtual oscillator control; and
generating a voltage command using the function.

9. The method of claim 8, further comprising using the voltage command to generate a second current command.

10. The method of claim 9, further comprising providing the second current command to a hysteretic current regulator for a DC/AC inverter.

11. The method of claim 8, wherein the determining step includes using a voltage regulator to determine the current command.

12. The method of claim 11, further comprising providing the current command to a delay block to execute the delaying step.

13. The method of claim 8, further comprising receiving an enable signal at a selector switch connected to the virtual oscillator control to begin the initialization process.

14. The method of claim 13, wherein the selector switch reads the delayed command current.

15. A micro-inverter comprising:
an hysteretic current regulator;
a virtual oscillator control (VOC) configured to generate a voltage command;
a voltage regulator configured to convert the voltage command to the current command; and
a delay circuit, the delay circuit configured to receive a current command from the voltage regulator during a startup online cycle and to send the received current command to the VOC after at least a predetermined period of time has passed,
wherein the startup initialization cycle continues until an output current regulated by the hysteretic current regulator synchronizes with an alternating current being supplied to a load.

16. The micro-inverter of claim 15 further comprising:
a switch, the switch coupled to the VOC and configured to select between multiple inputs and convey one or more of them to the VOC.

17. The micro-inverter of claim 15 wherein the startup initialization cycle begins upon receiving an enable signal at the VOC, the enable signal including initial configurations for the VOC.

18. The micro-inverter of claim 15 wherein the VOC is configured to rely solely on the received current command during the startup online cycle.

19. The micro-inverter of claim 15 wherein the voltage regulator is configured to receive the voltage command from the VOC and receive a real-time voltage signal and use the voltage command and the voltage signal to determine the current command.

20. The micro-inverter of claim 15 wherein during the startup online cycle the VOC is configured to use the received current command to determine subsequent voltage commands determined by the VOC.
